(19) United States
(12) Patent Application Publication
(10) Pub. No.: US 2022/0165976 A1
(43) Pub. Date: May 26, 2022

(54) DISPLAY DEVICE

(71) Applicant: Japan Display Inc., Tokyo (JP)

(72) Inventor: Tohru Sasaki, Tokyo (JP)

(21) Appl. No.: 17/665,646

(22) Filed: Feb. 7, 2022

Related U.S. Application Data
(63) Continuation of application No. PCT/JP2020/027830, filed on Jul. 17, 2020.

(30) Foreign Application Priority Data
Aug. 9, 2019 (JP) 2019-147846

(51) Int. Cl. H01L 51/50

(52) U.S. Cl. CPC H01L 51/5088; H01L 51/5056

(57) ABSTRACT

To provide a display device capable of more reliably preventing a leakage current between adjacent pixels, the display device includes a plurality of first electrodes, an organic insulating layer disposed in a non-light emitting area and covering an end portion of the first electrode, a first light emitting layer disposed on one first electrode and a second light emitting layer, a second electrode, a carrier transport layer, a carrier injection layer, and a first carrier blocking layer. The carrier injection layer includes an overlapping area that overlaps with an end portion of the organic insulating layer. The carrier transport layer overlaps with the carrier injection layer in the overlapping area. The first carrier blocking layer is disposed in the non-light emitting area, and an end portion of the first carrier blocking layer is disposed between the carrier transport layer and the carrier injection layer in the overlapping area.

### CROSS-REFERENCE TO RELATED APPLICATION

The present application is Bypass Continuation of International Application No. PCT/JP2020/027830, filed on Jul. 17, 2020, which claims priority from Japanese Application No. JP2019-147846 filed on Aug. 9, 2019. The contents of these applications are hereby incorporated by reference into this application.

### BACK GROUND OF THE INVENTION

### 1. Field of the Invention

The present invention relates to a display device.

### 2. Description of the Related Art

An organic electroluminescent (EL) display device includes a thin film transistor (TFT) and an organic light-emitting diode (OLED) that are formed on a substrate. The OLED includes an organic layer between a pair of electrodes. The organic layer is formed of a lamination of a hole transport layer, a light emitting layer, and an electron transport layer, for example. Such an organic layer is typically formed in an area surrounded by a convex bank, which is provided beforehand for partitioning pixels, and on the bank.

For example, when a conductive material such as a hole transport layer is provided in common between a plurality of pixels, a leakage current may flow between adjacent pixels. Specifically, the leakage current may cause the adjacent pixels, which should not emit light originally, to emit light, resulting in a decrease in contrast and color purity. Such problems may occur at remarkable rates as the high definition (e.g., the shortened distance between adjacent pixels) and the reduced driving voltage (e.g., use of a high mobility material) are developed.

To address the above problems, JP2008-243559A discloses removing the hole transport layer formed on the upper portion of the partition wall serving as the path through which the leakage current flows.

### SUMMARY OF THE INVENTION

In addition to the hole transport layer, the organic layer includes a carrier injection layer, such as a hole injection layer and an electron injection layer. The carrier injection layer has smaller electrical resistance than the hole transport layer. As such, even when the hole transport layer formed on the upper portion of the partition wall is removed as described in JP2008-243559, if the carrier injection layer is disposed to cover the entire display area, the carrier injection layer becomes a path for the leakage current to flow.

One or more embodiments of the present invention have been conceived in view of the above, and an object thereof is to provide a display device capable of more reliably preventing a leakage current between adjacent pixels.

In order to solve the above problems, a display device according to the present invention includes a plurality of first electrodes, an organic insulating layer disposed in a non-light emitting area and covering an end portion of the first electrode, the non-light emitting area being between one first electrode and another first electrode among the plurality of first electrodes, a first light emitting layer disposed on one first electrode of the plurality of first electrodes and a second light emitting layer disposed on another first electrode of the plurality of first electrodes, a second electrode on the first light emitting layer and the second light emitting layer, a carrier transport layer between the first electrode and the second electrode, a carrier injection layer between the first electrode and the second electrode, and a first carrier blocking layer disposed on the carrier injection layer in an area in which the organic insulating layer is disposed. The carrier injection layer includes an overlapping area that overlaps with an end portion of the organic insulating layer. The carrier transport layer overlaps with the carrier injection layer in the overlapping area. The first carrier blocking layer is disposed in the non-light emitting area, and an end portion of the first carrier blocking layer is disposed between the carrier transport layer and the carrier injection layer in the overlapping area.

According to the present invention, it is possible to more reliably suppress leakage current between neighboring pixels in a display device.

### BRIEF DESCRIPTION OF THE DRAWINGS

FIG. 1 is a schematic diagram illustrating a configuration of an organic EL display device according to the present embodiment;

FIG. 2 is a schematic plan view of an example of the organic EL display device according to the present embodiment;

FIG. 3 is an enlarged plan view of a periphery of pixels in FIG. 2;

FIG. 4 is a diagram showing an example of a cross section taken along the line IV-IV in FIG. 3;

FIG. 5 is a diagram showing an example of a cross section according to the second embodiment;

FIG. 6 is a diagram showing an example of a cross section according to the third embodiment;

FIG. 7 is a diagram showing an example of a cross section according to the fourth embodiment;

FIG. 8 is a diagram showing a modification of a carrier blocking layer and a hole injection layer; and

FIG. 9 is a diagram showing another modification of a carrier blocking layer and a hole injection layer.

### DETAILED DESCRIPTION OF THE INVENTION

### [First Embodiment]

Embodiments of the present invention will be described below in detail with reference to the accompanying drawings.

The accompanying drawings referred to in the following description may schematically illustrate widths, thicknesses, shapes, or other characteristics of each part for clarity of illustration, compared to actual configurations. However, such a schematic illustration is merely an example and not intended to limit the present invention. In this specification and each drawing, the same elements as those already described with reference to the already-presented drawings are denoted by the same reference numerals, and detailed description thereof may be appropriately omitted.

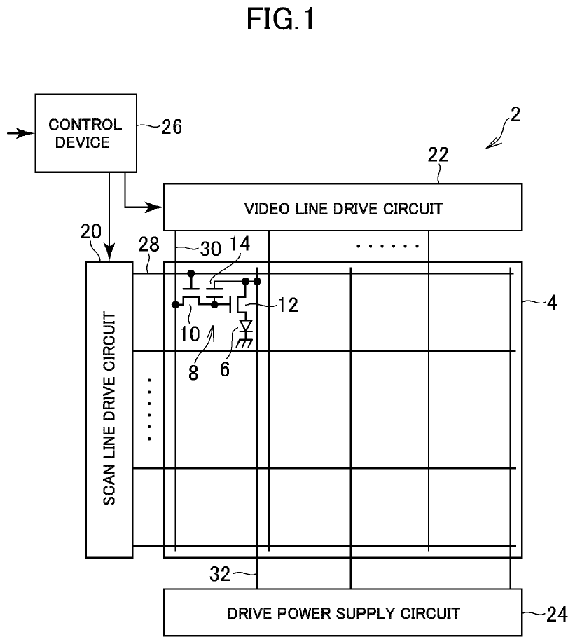

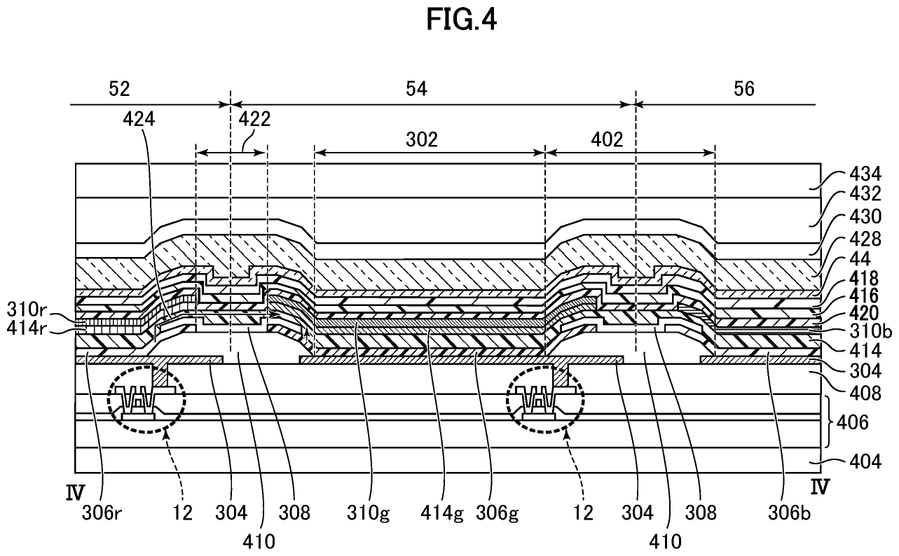

FIG. 1 is a schematic diagram showing a configuration of an organic EL display device 2 according to the present embodiment. The organic EL display device 2 includes a pixel array unit 4 for displaying an image, and a driving unit for driving the pixel array unit 4. The organic EL display device 2 has a structure in which a laminated structure, such as TFTs 10 and 12 and an OLED 6, is formed on a substrate 404 (see FIG. 4). The schematic diagram shown in FIG. 1 is merely an example, and the present embodiment is not limited to this example.

In the pixel array unit 4, the OLED 6 and a pixel circuit 8 are arranged in a matrix with respect to pixels. The pixel circuit 8 is composed of a plurality of TFTs 10 and 12 and a capacitor 14.

The driving unit includes a scan line drive circuit 20, a video line drive circuit 22, a drive power supply circuit 24, and a control device 26, drives the pixel circuit 8, and controls the emission of the OLED 6.

The scan line drive circuit 20 is connected to scan signal lines 28 each provided for a horizontal pixel array (pixel row). The scan line drive circuit 20 sequentially selects the scan signal lines 28 in response to a timing signal input from the control device 26 and applies a voltage to turn on the lighting TFT 10 to the selected scan signal line 28.

The video line drive circuit 22 is connected to video signal lines 30 each provided for a vertical pixel array (pixel column). The video line drive circuit 22 receives a video signal from the control device 26 and outputs a voltage corresponding to the video signal of the selected pixel row to each video signal line 30 in accordance with the selection of the scan signal line 28 by the scan line drive circuit 20. The voltage is written to the capacitor 14 via the lighting TFT 10 at the selected pixel row. The drive TFT 12 supplies a current corresponding to the written voltage to the OLED 6, whereby the OLED 6 of the pixel corresponding to the selected scan signal line 28 emits light.

The drive power supply circuit 24 is connected to drive power supply lines 32 respectively provided for pixel columns, and supplies a current to the OLED 6 via the drive power supply line 32 and the drive TFT 12 in the selected pixel row.

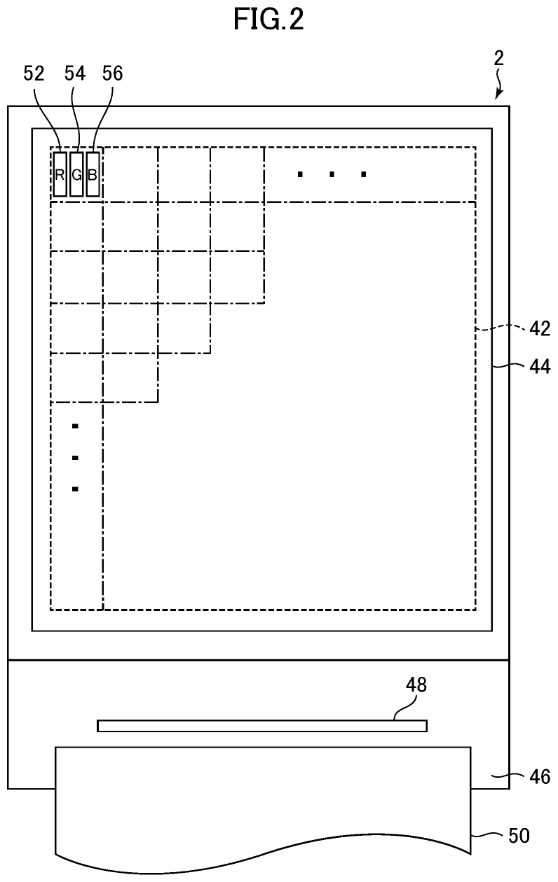

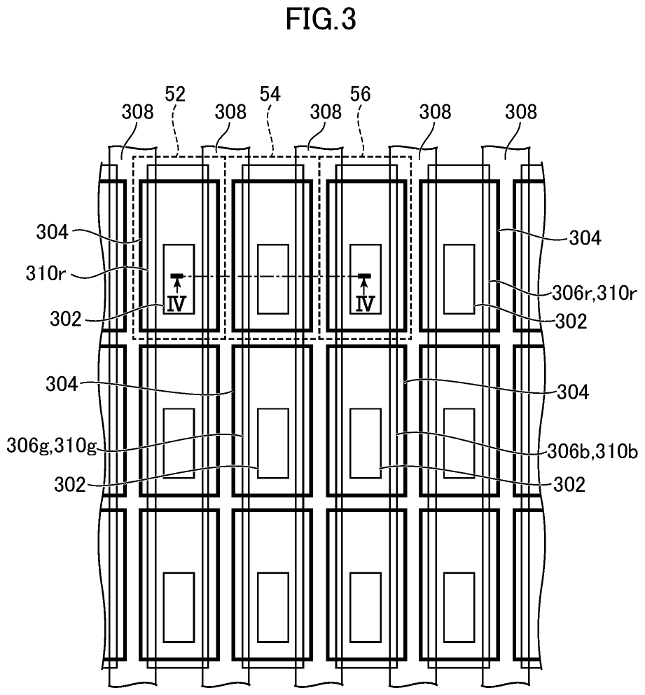

A first electrode 304 (see FIGS. 3 and 4) of the OLED 6 is connected to the drive TFT12. A second electrode 44 (see FIGS. 2 and 4) of the OLED 6 is composed of electrodes common to the OLEDs 6 of all the pixels. When the first electrode 304 is formed as an anode, a high electric potential is entered in the first electrode, and the second electrode 44 is formed as a cathode and supplied with a low electric potential. When the first electrode 410 is formed as a cathode, a low electric potential is entered in the first electrode, and the second electrode 44 is formed as an anode and supplied with a high electric potential.

FIG. 2 is a schematic plan view of an example of the organic EL display device 2 shown in FIG. 1. The display area 42 of the organic EL display device 2 includes the pixel array unit 4 shown in FIG. 1, and the OLED 6 is arranged in the pixel array unit 4 as described above. As described above, the second electrode 44 constituting the OLED 6 is commonly formed in the pixels and covers the entire display area 42.

On one side of the organic EL display device 2, which is rectangular, a component mounting area 46 is provided, where the wires to the display area 42 are disposed. The component mounting area 46 includes a driver integrated circuit (IC) 48 constituting the driving unit, and is connected to a flexible printed circuit board (FPC50). The FPC 50 is connected to the control device 26 or other circuits 20, 22, and 24, for example, or includes an IC mounted thereon.

Each pixel is composed of a plurality of sub-pixels. Specifically, for example, each pixel includes a first sub-pixel 52 that emits red light, a second sub-pixel 54 that emits green light, and a third sub-pixel 56 that emits blue light.

FIG. 3 is an enlarged plan view of the periphery of the pixels in FIG. 2. FIG. 4 is a diagram showing an example of a cross section taken along the line IV-IV in FIG. 3. As shown in FIGS. 3 and 4, the organic EL display device 2 includes a substrate 404, an array layer 406, a flattening film 408, a first electrode 304, an organic insulating layer 410, an organic layer, a second electrode 44, a cap layer 428, and a sealing film.

The substrate 404 is formed of, for example, resin and has flexibility. The substrate 404 may be formed of glass.

The array layer 406 is formed on the substrate 404. Specifically, the array layer 406 is formed on the upper layer of the substrate 404 so as to include a plurality of lighting TFTs 10 and drive TFTs 12 configured to include a source electrode, a drain electrode, a gate electrode, and a semiconductor layer.

The flattening film 408 is formed of an insulating material on the array layer 406. The flattening film 408 has a through hole on one of the source electrode and the drain electrode of the drive TFT12. The flattening film 408 is formed of an insulating material so as to cover the array layer 406. For example, the flattening film 408 is formed of an organic insulating material such as acrylic or polyimide.

The first electrode 304 is formed on the flattening film 408. Specifically, the first electrode 304 is formed of a transparent and conductive material, such as ITO, and is electrically connected to the source electrode or the drain electrode of the drive TFT12 through a through hole. The method of extracting light of the organic EL includes a top emission system to be described later for extracting the light from the light emitting layer on the side opposite to the array layer 406 and a bottom emission system for extracting the light in the opposite direction to the top emission system. In the top emission system, the first electrode 304 may have a configuration of a laminate of silver and ITO, for example, in order to have light reflectivity.

The organic insulating layer 410 is disposed in a non-light emitting area 402. Specifically, the organic insulating layer 410 is formed so as to cover the flattening film 408 in an area where the first electrode 304 is not formed, and is formed on the first electrode 304 at the end portion of the first electrode 304. The organic insulating layer 410 is disposed in the non-light emitting area. The area where the organic insulating layer 410 is not provided is an opening of the organic insulating layer 410. The opening of the organic insulating layer 410 is a light emitting area 302 from which light is extracted from the light emitting layer. The organic insulating layer 410 may be an organic insulating layer, such as acrylic and polyimide.

The organic layer includes a light emitting layer, a carrier transport layer, a carrier injection layer, a first carrier blocking layer 308, and a second carrier blocking layer 420.

The light emitting layer emits light by means of electrons and holes supplied from the second electrode 44 and the first electrode 304. Specifically, for example, the light emitting layer includes a first light emitting layer 310r that emits red light, a second light emitting layer 310g that emits green light, and a third light emitting layer 310b that emits blue light. In a cross-sectional view, the first light emitting layer 310r to the third light emitting layer 310b are arranged with the organic insulating layer 410 interposed therebetween. For example, the first light emitting layer 310r and the second light emitting layer 310g are disposed on both sides of the organic insulating layer 410. The second light emitting layer 310g and the third light emitting layer 310b are disposed on both sides of the organic insulating layer 410.

The carrier transport layer is disposed on and below the first light emitting layer 310r to the third light emitting layers 310b. Specifically, for example, the carrier transport layer includes a hole transport layer and an electron transport layer 416. When the first electrode 304 is an anode, the hole transport layer is disposed below the first light emitting layer 310r to the third light emitting layer 310b, and the electron transport layer 416 is disposed on the first light emitting layer 310r to the third light emitting layer 310b.

The hole transport layer may be composed of a first hole transport layer 414 provided in common to the first sub-pixel 52, the second sub-pixel 54, and the third sub-pixel 56, a second hole transport layer 414r provided only on the first hole transport layer 414 of the first sub-pixel 52, and a third hole transport layer 414g provided only on the first hole transport layer 414 of the second sub-pixel 54. Each hole transport layer provided on each light emitting layer is formed with a thickness corresponding to the wavelength of light emitted by each sub-pixel. This forms a so-called microcavity structure.

The carrier injection layer is disposed between the first electrode 304 and the second electrode 44. The carrier injection layer has an overlapping area that overlaps with the end portion of the organic insulating layer 410. In the overlapping area, the carrier transport layer and the carrier injection layer overlap with each other. For example, the carrier injection layer is disposed between the carrier transport layer and the first electrode 304 and on the organic insulating layer 410 (overlaps with the organic insulating layer 410). The end portion of the carrier injection layer overlaps with the end portion of the organic insulating layer 410. The carrier injection layer includes a hole injection layer and an electron injection layer 418. The hole injection layer is disposed below the hole transport layer in the light emitting area 302, and the electron injection layer 418 is disposed on the electron transport layer 416 in the light emitting area 302. The carrier injection layer is disposed between the carrier transport layer and the first electrode 304 in the area overlapping the end portion of the organic insulating layer 410.

The hole injection layer is provided on the first electrode 304 for each sub-pixel that emits light of a different color. Specifically, the hole injection layer is provided for each of the first sub-pixel 52, the second sub-pixel 54, and the third sub-pixel 56. As shown in FIG. 3, the first sub-pixel 52, the second sub-pixel 54, and the third sub-pixel 56 are each arranged in the vertical direction in a plan view. A first hole injection layer 306r is disposed in the first sub-pixel 52, a second hole injection layer 306g is disposed in the second sub-pixel 54, and a third hole injection layer 306b is disposed in the third sub-pixel 56. As such, the hole injection layers of the respective sub-pixels arranged vertically in a plan view are connected, and the hole injection layers of the respective sub-pixels arranged horizontally are separated. That is, as shown in FIG. 4, the hole injection layer includes a blocking area 422 having a hole in the area on the organic insulating layer 410 in a cross-sectional view. The blocking area 422 serves to reduce the leakage current generated through the hole injection layer between the sub-pixels emitting different colors. The hole injection layer may be separated between adjacent sub-pixels, and may be formed in an island shape in a plan view, for example, as described later. For example, when different colors are arranged not only in the horizontal direction but also in the vertical direction, the hole injection layer may be formed in an island shape.

The hole injection layer is disposed so as to run on the end portion of the organic insulating layer 410. In FIG. 4, the electron transport layer 416 is disposed across the pixels of different colors, although the electron transport layer 416 may have the same structure as the hole transport layer. Further, the electron injection layer 418 is also disposed across the pixels of different colors, although the electron injection layer 418 may have the same structure as the hole injection layer.

The first carrier blocking layer 308 is disposed on the carrier injection layer in an area where the organic insulating layer 410 is disposed. The first carrier blocking layer 308 is disposed in the non-light emitting area 402, and the end portion of the first carrier blocking layer 308 is disposed between the carrier transport layer and the carrier injection layer in the overlapping area. Specifically, the first carrier blocking layer 308 is disposed between the hole transport layer and the hole injection layer in the area on the organic insulating layer 410 in a cross-sectional view. The first carrier blocking layer 308 is formed of an organic material that blocks a leakage current, and has higher electric resistance than the hole injection layer and the hole transport layer, i.e., has lower mobility of holes. For example, the first carrier blocking layer 308 is formed of the same material as the hole blocking layer, the electron injection layer 418, or the electron transport layer 416. The first carrier blocking layer 308 may be formed of a lamination of the hole blocking layer, the electron injection layer 418, and the electron transport layer 416. The first carrier blocking layer 308 is formed to have a thickness of 100 nm or less.

The first carrier blocking layer 308 is disposed across the boundaries of the sub-pixels emitting light in different colors in a plan view. Specifically, as shown in FIG. 3, the first carrier blocking layer 308 is disposed in the non-light emitting area 402 between the sub-pixels arranged in the left-right direction. The first carrier blocking layer 308 may not be disposed in the non-light emitting area 402 between the sub-pixels arranged in the vertical direction. As such, the first carrier blocking layer 308 has a striped shape that is long in the vertical direction in FIG. 3.

The voltage corresponding to the displayed image is applied to the first electrode 304 of the adjacent sub-pixels. When there is a difference in the voltage between adjacent sub-pixels, a leakage current flows between adjacent sub-pixels. The main path through which the leakage current flows is the hole injection layer and the hole transport layer disposed in the non-emitting area 402.

The first carrier blocking layer 308 has higher electrical resistance (lower mobility of holes) than the hole injection layer and the hole transport layer, and thus the leakage current can be reduced by disposing the first carrier blocking layer 308 between the hole injection layer and the hole transport layer.

The first carrier blocking layer 308 is disposed in an area on the organic insulating layer 410 so as to cover the blocking area 422 of the hole injection layer. Further, in a cross-sectional view, the end portion of the first carrier blocking layer 308 on the first light emitting layer 310r side is located closer to the light emitting area 302 than the end portion of the blocking area 422 on the first light emitting layer 310r side. In a cross-sectional view, the end portion of the first carrier blocking layer 308 on the second light emitting layer 310g side is located closer to the light emitting area 302 than the end portion of the blocking area 422 on the second light emitting layer 310g side. That is, the first carrier blocking layer 308 has an area overlapping with the hole injection layer in the area on the organic insulating layer 410.

If the first carrier blocking layer 308 is not provided, there is a path in which the leakage current flows from the end portion of the hole injection layer of the first sub-pixel 52 to the hole injection layer of the second sub-pixel 54 through the hole transport layer of the blocking area 422. In this regard, according to the above embodiment, the leakage current flowing from the first hole injection layer 306r to the second hole injection layer 306g flows through the path 424 indicated by the arrow in FIG. 4. The hole transport layer has higher electrical resistance than the hole injection layer, and thus the leakage current can be reduced by providing a longer length of the path 424 by which the leakage current flows through the hole transport layer.

The second carrier blocking layer 420 is disposed between the first light emitting layer 310r to the third light emitting layer 310b and the carrier transport layer in the light emitting area 302. Specifically, as shown in FIG. 4, the second carrier blocking layer 420 is disposed between each of the first light emitting layer 310r to the third light emitting layer 310b and the electron transport layer 416. The second carrier blocking layer 420 is a hole blocking layer that prevents holes supplied from the first electrode 304 from reaching the electron transport layer 416. Although not shown in FIG. 4, an electron blocking layer for preventing electronics supplied from the second electrode 44 from reaching the hole transporting layer may be disposed between each of the first light emitting layer 310r to the third light emitting layer 310b and the hole transporting layer in the light emitting area 302.

The second electrode 44 is disposed on the organic layer. More specifically, the second electrode 44 is formed of a material having a conductive property together with a light-transmittance property and a light-reflecting property, such as MgAg, so as to cover the organic layer. In this embodiment, the second electrode 44 is formed continuously across a plurality of sub-pixels. The second electrode 44 supplies electronics to the organic layer to cause the first light emitting layer 310r to the third light emitting layer 310b to emit light. The cap layer 428 is disposed on the second electrode 44. The cap layer 428 may be formed to have a different thickness for sub-pixels having different colors. The cap layer 428 has a so-called microcavity structure.

The sealing film is disposed on the cap layer 428. Specifically, the sealing film is formed by one or more layers. In this embodiment, the sealing film is composed of a lamination of a first inorganic sealing film 430, an organic sealing film 432, and a second inorganic sealing film 434, and covers the cap layer 428. The sealing film prevents moisture from penetrating into the organic layer, thereby prevents deterioration of the organic layer.

As described above, the leakage current can be reduced by disposing the first carrier blocking layer 308.

In the above embodiment, the case is described in which the holes are supplied from the first electrode 304 to the light emitting layer and the electrons are supplied from the second electrode 44 to the light emitting layer, although the opposite configuration may also be employed.

That is, the electrons may be supplied to the light emitting layer from the first electrode 304, and the holes may be supplied from the second electrode 44 to the light emitting layer. In this case, the hole injection layer, the first carrier blocking layer 308, and the hole transport layer are disposed on the light emitting layer.

### [Second Embodiment]

Next, the second embodiment will be described. FIG. is a cross-sectional view of the organic EL display device 2 according to the second embodiment. Descriptions of the same configuration as that of the first embodiment are omitted.

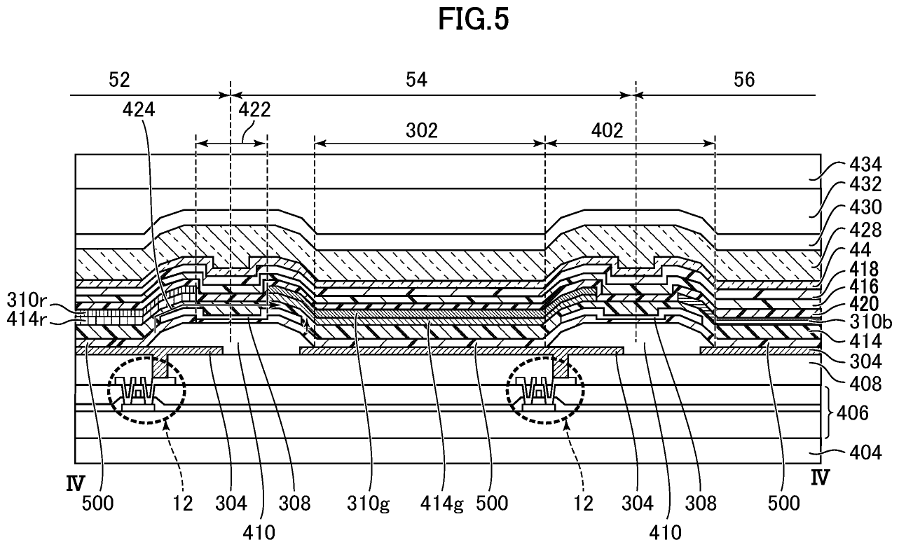

As shown in FIG. 5, the structure from the substrate 404 to the organic insulating layer 410 and the structure from the second electrode 44 to the sealing film are the same as those of the first embodiment. The second embodiment is also the same as the first embodiment in that the organic layer is disposed on the organic insulating layer 410 and the first electrodes 304, but is different from the first embodiment in that the carrier injecting layer has a blocking area 422 formed thinner than the other areas in the area on the organic insulating layer 410.

Specifically, a hole injection layer 500 included in the carrier injection layer is formed so as to cover the entire light emitting area 302 and the entire non-light emitting area 402, and has a blocking area 422 formed thinner than other areas on the organic insulating layer 410.

The hole injection layer 500 may be formed simultaneously for the first sub-pixel 52 to the third sub-pixel 56, or may be formed separately for each of the first sub-pixel 52, the second sub-pixel 54, and the third sub-pixel 56.

The first carrier blocking layer 308 is disposed on the organic insulating layer 410. Specifically, the first carrier blocking layer 308 is disposed so as to cover the blocking area 422. The first carrier blocking layer 308 also includes an area overlapping with the hole injection layer 500 (the hole injection layer 500 formed in an area other than the blocking area 422) in the area on the organic insulating layer 410. This can increase the length of a leak path 424 through the hole transport layer.

In general, the hole injection layer 500 is formed with the use of a mask covering the blocking area 422. When the organic EL display device 2 is high definition, the distance between adjacent sub-pixels is short, and thus the material of the hole injecting layer 500 may enter into and adhere to the area covered with the mask. The material of the hole injection layer 500 that is entered and adhered forms a thin hole injection layer 500 in the blocking area 422. That is, according to the second embodiment, it is possible to provide an organic EL display device 2 having higher definition. Further, the hole injection layer 500 formed by the material entered around the mask is very thin, and thus the leakage current through the hole injection layer 500 is small.

For example, when the hole injection layer 500 is individually formed for each of the first sub-pixel 52, the second sub-pixel 54, and the third sub-pixel 56, the end portions of the respective hole injection layers 500 are thinner. At this time, if the distance between adjacent sub-pixels of the hole injection layers 500 is not sufficiently enough, the end portions of the respective hole injection layers 500 may come into contact with each other. However, the first carrier blocking layer 308 covers the end portions of the respective hole injection layers 500, and thus the leakage path 424 can be made sufficiently long to reduce the leakage current. Further, the distance between the end portions of the respective hole injection layer 500 is shortened, which eventually serves to achieve a high definition.

As described above, according to the second embodiment, it is possible to provide an organic EL display device 2 having higher definition while reducing the leakage current.

### [Third Embodiment]

Next, the third embodiment will be described. FIG. is a cross-sectional view of the organic EL display device 2 according to the third embodiment. Descriptions of the same configuration as that of the first embodiment are omitted.

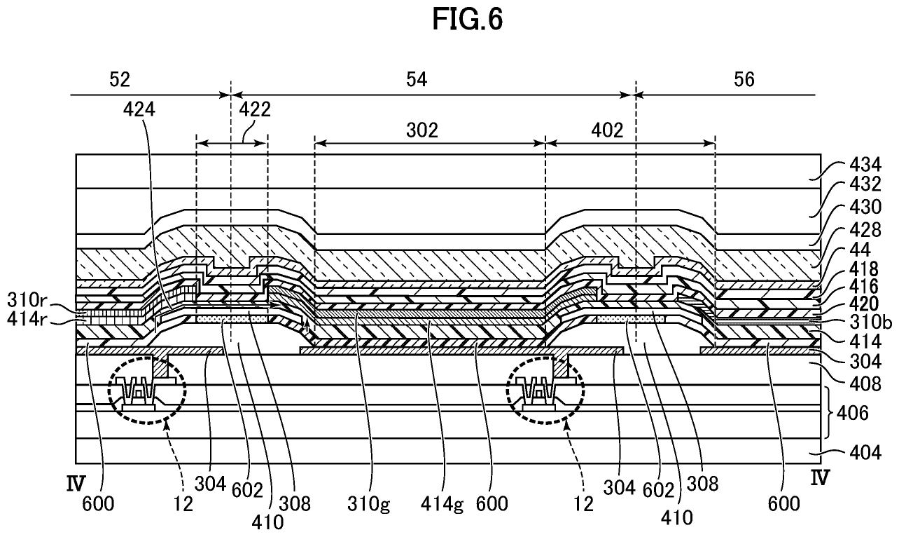

As shown in FIG. 6, the structure from the substrate 404 to the organic insulating layer 410 and the structure from the second electrode 44 to the sealing film are the same as those of the first embodiment. The third embodiment is the same as the first embodiment in that the organic layer is disposed on the organic insulating layer 410 and the first electrodes 304, but is different from the first embodiment in that the hole injection layer 600 included in the carrier injection layer has a blocking area 422 having lower conductivity in an area on the organic insulating layer 410.

Specifically, in the third embodiment, the hole injection layer 600 disposed on the organic insulating layer 410 includes an area having the conductivity that is lowered due to the deterioration of the physical properties thereof. The deterioration of the physical properties of the hole injection layer 600 means that, when comparing the area that is not deteriorated and the area that is deteriorated, the elements of the multiple elements included in the hole injection layer 600 are the same but the physical properties of the elements are different.

The blocking area 422 is formed by selectively irradiating the hole injection layer 600 on the organic insulating layer 410 with energy beam from the opposite side of the organic insulating layer 410 (the surface direction opposite to the surface where the organic layer is in contact with the organic insulating layer 410). The energy beam can alter and deteriorate the organic molecules of the organic layer, and, for example, ultraviolet light, infrared light, electron beam, and high intensity white light are used. In this case, it is preferable that the energy beam has a wavelength that can be absorbed by the hole injection layer 600. By irradiating the energy beam in this way, the organic layer on the organic insulating layer 410 includes the blocking area 422 having low conductivity. This serves to reduce the leakage current flowing between adjacent sub-pixels.

The blocking area 422 may be formed between all of the sub-pixels, or may be selectively formed around a specific sub-pixel (e.g., around the second sub-pixel 54 in which a decrease in color purity due to leakage current is remarkable among the first sub-pixel 52, the second sub-pixel 54, and the third sub-pixel 56). The blocking area 422 may not be provided between the sub-pixels of the same color.

The first carrier blocking layer 308 is disposed in an area on the organic insulating layer 410 so as to cover the blocking area 422 of the hole injection layer 600. In a cross-sectional view, the end portion of the first carrier blocking layer 308 on the first light emitting layer 310r side is located closer to the light emitting area 302 than the end portion of the blocking area 422 on the first light emitting layer 310r side. Further, in a cross-sectional view, the end portion of the first carrier blocking layer 308 on the second light emitting layer 310g side is located closer to the light emitting area 302 than the end portion of the blocking area 422 on the second light emitting layer 310g side. That is, the first carrier blocking layer 308 includes an area that covers the hole injection layer 602 that is deteriorated in the area on the organic insulating layer 410 and overlaps with the hole injection layer 600 that is not deteriorated.

As such, similarly to the first embodiment, the leakage current can be reduced by providing a longer length of the path 424 by which the leakage current flows through the hole transport layer.

### [Fourth Embodiment]

Next, the fourth embodiment will be described. FIG. is a cross-sectional view of the organic EL display device 2 according to the fourth embodiment. Descriptions of the same configuration as that of the first embodiment are omitted.

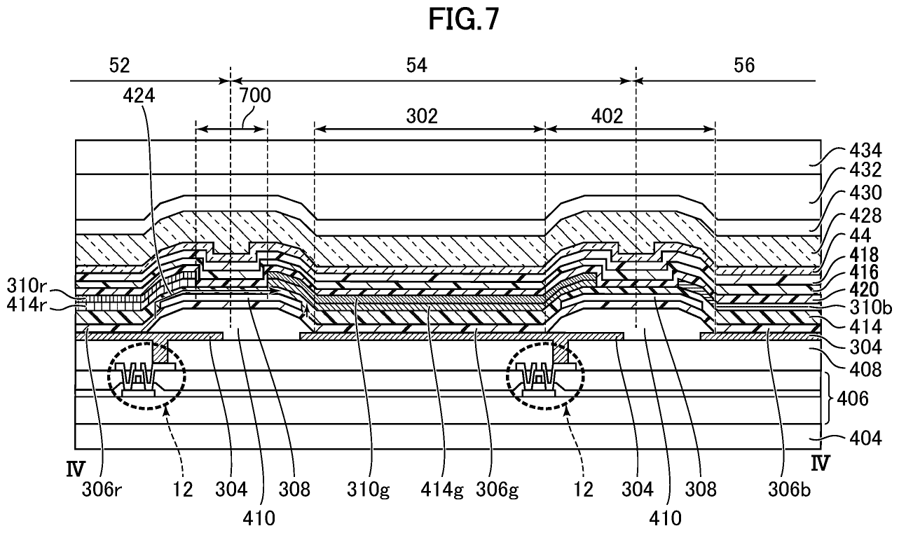

As shown in FIG. 7, the structure from the substrate 404 to the organic insulating layer 410 and the structure from the second electrode 44 to the sealing film are the same as those of the first embodiment. The fourth embodiment is the same as the first embodiment in that the organic layer is disposed on the organic insulating layer 410 and the first electrode 304, but is different from the first embodiment in that the blocking area 422 is not provided in the area on the organic insulating layer 410 and in the lower layer than the light emitting layer.

According to the fourth embodiment, the hole injecting layer is formed to have a uniform thickness over the entire displaying area 42. The first carrier blocking layer 308 is disposed between the carrier transporting layer and the carrier injection layer in an area 700 (corresponding to the blocking area 422 of the first to third embodiments) on the organic insulating layer 410. Similarly to the first embodiment, the first carrier blocking layer 308 is formed to a thickness of 100 nm or less. Further, the hole transport layer is disposed on the first carrier blocking layer 308.

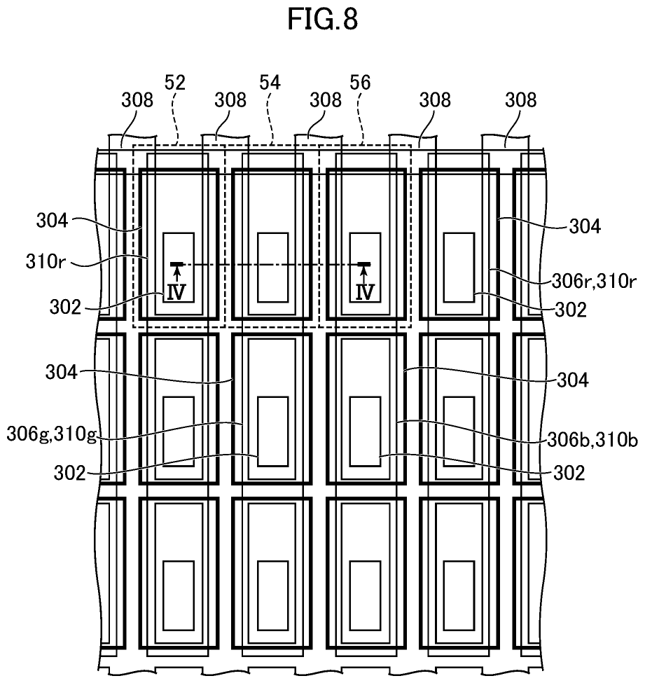

FIG. 8 is a diagram showing a modification of the first carrier blocking layer 308 and the hole injection layer. The first hole injection layer 306r to the third hole injection layer 306b may be provided in an island shape for each sub-pixel. When different colors are arranged not only in the horizontal direction but also in the vertical direction, the first hole injection layer 306r to the third hole injection layer 306b may be provided in an island shape. Although not shown, the first hole injection layer 306r to the third hole injection layer 306b may be provided in an island shape for each of a plurality of sub-pixels. In this case, the first carrier blocking layer 308 is provided in a grid shape as shown in FIG. 8, and thereby covering all end portions of the hole injection layer. This serves to reduce the leakage current through the hole transport layer. The first carrier blocking layer 308 may cover only the long side of the hole transport layer of the adjacent pixels. In this case, as shown in FIG. 3, the first carrier blocking layer 308 has a striped shape.

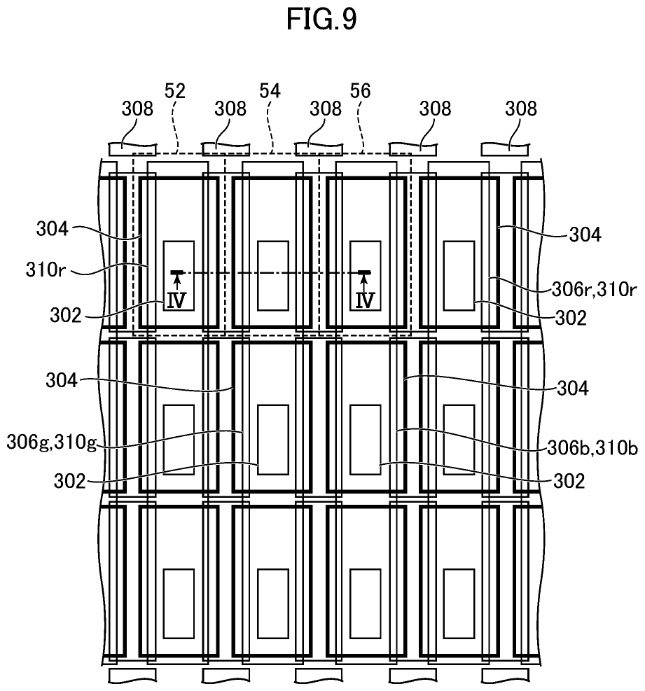

FIG. 9 is a diagram showing another modification of the first carrier blocking layer 308. As shown in FIG. 9, the first carrier blocking layer 308 may be provided in an island shape. In this case, the first carrier blocking layer 308 covers only the long side of the hole transport layer of the adjacent pixels. Although not shown, the first carrier blocking layer 308 may be provided in an island shape for each of a plurality of sub-pixels. In FIG. 9, the hole injection layer is formed in a striped shape, but may be formed in an island shape as shown in FIG. 8.

According to this structure, the hole injection layer can be formed without using a mask, and thus the load on the manufacturing process can be reduced. Further, the step made by the first carrier blocking layer 308 serves to form the hole transport layer thinner or discontinuously in some cases on the end portion of the first carrier blocking layer 308. Further, the leakage path 424 passing through the hole transport layer can be made longer by the thickness of the first carrier blocking layer 308. As such, according to the fourth embodiment, it is possible to reduce the leakage current through the hole transporting layer.

While there have been described what are at present considered to be certain embodiments of the invention, it will be understood that various modifications may be made thereto, and it is intended that the appended claims cover all such modifications as fall within the true spirit and scope of the invention.

What is claimed is:

1. A display device comprising:
a plurality of first electrodes;
an organic insulating layer disposed in a non-light emitting area and covering an end portion of the first electrode, the non-light emitting area being between one first electrode and another first electrode among the plurality of first electrodes;
a first light emitting layer disposed on one first electrode of the plurality of first electrodes and a second light emitting layer disposed on another first electrode of the plurality of first electrodes;
a second electrode on the first light emitting layer and the second light emitting layer;
a carrier transport layer between the first electrode and the second electrode;
a carrier injection layer between the first electrode and the second electrode; and
a first carrier blocking layer disposed on the carrier injection layer in an area in which the organic insulating layer is disposed, wherein
the carrier injection layer includes an overlapping area that overlaps with an end portion of the organic insulating layer,
the carrier transport layer overlaps with the carrier injection layer in the overlapping area, and
the first carrier blocking layer is disposed in the non-light emitting area, and an end portion of the first carrier blocking layer is disposed between the carrier transport layer and the carrier injection layer in the overlapping area.

2. The display device according to claim 1, wherein
the non-light emitting area includes a blocking area, and
the blocking area does not include the carrier injection layer.

3. The display device according to claim 1, wherein
the carrier injection layer includes a blocking area in the non-light emitting area, and
the carrier injection layer is thinner in the blocking area than in other areas.

4. The display device according to claim 1, wherein
the carrier injection layer includes a blocking area in the non-light emitting area, and
the carrier injection layer has lower conductivity in the blocking area than in other areas.

5. The display device according to claim 2, wherein
the blocking area and the first carrier blocking layer overlap with each other in a plan view.

6. The display device according to claim 2, wherein
the first carrier blocking layer is formed in a striped shape in the non-light emitting area.

7. The display device according to claim 2, wherein
the first carrier blocking layer is formed in a grid shape in the non-light emitting area.

8. The display device according to claim 2, wherein
the first carrier blocking layer is formed in an island shape in the non-light emitting area.

9. The display device according to claim 2, wherein
the first carrier blocking layer covers the blocking area, and
the end portion of the first carrier blocking layer on the first light emitting layer side is located closer to a light emitting area than the end portion of the blocking area on the first light emitting layer side.

10. The display device according to claim 1, further comprising a second carrier blocking layer between the first and second light emitting layers and the carrier transport layer.
